(19) United States
(12) Patent Application Publication
(10) Pub. No.: US 2023/0268454 A1
(43) Pub. Date: Aug. 24, 2023

(54) MANUFACTURING METHOD OF DISPLAY DEVICE AND APPARATUS FOR MANUFACTURING DISPLAY DEVICE

(71) Applicant: Samsung Display Co., LTD., Yongin-si (KR)

(72) Inventor: Jeong Won HAN, Yongin-si (KR)

(21) Appl. No.: 17/889,777

(22) Filed: Aug. 17, 2022

(30) Foreign Application Priority Data
Jan. 21, 2022 (KR) 10-2022-0009467

(51) Int. Cl. H01L 33/00; H01L 27/15; H01L 33/24; H01L 33/44

(52) U.S. Cl. CPC H01L 33/005; H01L 27/156; H01L 33/24; H01L 33/44

(57) ABSTRACT

A method of manufacturing a display device, a display device, and an apparatus for manufacturing a display device are provided. A method of manufacturing a display device includes: providing an ink including light emitting elements on a manufacturing substrate; and aligning the light emitting elements by using a mold including a plurality of groove patterns.

### CROSS-REFERENCE TO RELATED APPLICATION

This application claims priority to and the benefit of Korean Patent Application No. 10-2022-0009467, filed on Jan. 21, 2022 in the Korean Intellectual Property Office, the entire disclosure of which is incorporated herein by reference.

### BACKGROUND

### 1. Field

Aspects of embodiments of the present disclosure generally relate to a manufacturing method of a display device, a display device, and an apparatus for manufacturing a display device.

### 2. Related Art

Recently, as interest in information displays is increasing, research and development of display devices have been continuously conducted.

### SUMMARY

According to aspects of embodiments of the present disclosure, a manufacturing method of a display device, a display device, and an apparatus for manufacturing a display device, which can improve an alignment degree of a light emitting element, are provided.

In accordance with one or more embodiments of the disclosure, a method of manufacturing a display device includes: providing an ink including light emitting elements on a manufacturing substrate; and aligning the light emitting elements by using a mold including a plurality of groove patterns.

The aligning of the light emitting elements may include: allowing a press arranged on a surface of the mold to push the mold; allowing the mold to apply a pressure to the light emitting elements; and allowing the light emitting elements to be aligned corresponding to the plurality of groove patterns of the mold.

The mold may include light emitting element areas. The allowing of the mold to apply the pressure to the light emitting elements may be performed such that positions at which the light emitting elements are aligned respectively correspond to positions of the light emitting element areas.

The light emitting element areas may be groove areas formed in the mold.

The aligning of the light emitting elements may include allowing the plurality of groove patterns of the mold to contact the light emitting elements located on the manufacturing substrate.

The mold may have a roller shape. The aligning of the light emitting elements may include allowing the mold to be rolled on the manufacturing substrate.

The aligning of the light emitting elements may include allowing the mold to apply a pressure to the light emitting elements when a press having a roller shape is rolled on the mold.

The method may further include providing a bank protruding in a thickness direction of the manufacturing substrate on the manufacturing substrate. The providing of the ink may include allowing the ink to be accommodated in a space defined by the bank. The mold may include: a base part; and a protrusion part connected to the base part. The mold may include a mold movement restriction area in which the protrusion part is not located. The aligning of the light emitting elements may include: allowing a portion of the mold to apply a pressure to the light emitting elements; and allowing the mold to contact the bank in the mold movement restriction area.

The method may further include allowing a cleaner to clean a surface of the mold, after the aligning of the light emitting elements.

The method may further include allowing a cleaner to clean a surface of the mold, wherein the mold has a roller shape. An area of an outer surface of the mold according to a circumference of the mold may be smaller than an area of the manufacturing substrate. The cleaning of the surface of the mold may be concurrently performed with the aligning of the light emitting elements.

The method may further include: providing an alignment electrode on the manufacturing substrate; and forming an electric field by using the alignment electrode. The light emitting elements may be aligned based on the electric field.

The forming of the electric field and the aligning of the light emitting elements by using the mold may be concurrently performed.

The mold may include: a base part; and a protrusion part connected to the base part. The protrusion part may include a light emitting element area formed such that a portion of the protrusion part is recessed. A direction in which the light emitting elements aligned on the manufacturing substrate extend may be the same as a direction in which the light emitting element area extends.

The mold may have an elastic property.

In accordance with one or more embodiments of the disclosure, a display device manufactured according to the method is provided.

In accordance with one or more embodiments of the disclosure, an apparatus for manufacturing a display device includes: a mold located on a stage; and a press configured to apply, to the mold, a pressure facing the stage from the mold, wherein the mold includes: a base part; and a protrusion part connected to the base part, the protrusion part including a groove area formed such that a portion of the protrusion part is recessed.

The mold may have a roller shape.

The press may have a roller shape.

The apparatus may further include a probe arranged on the stage, the probe configured to provide an electrical signal such that an electric field is formed on a manufacturing substrate provided on the stage.

### BRIEF DESCRIPTION OF THE DRAWINGS

Some example embodiments will now be described more fully herein with reference to the accompanying drawings; however, the present disclosure may be embodied in different forms and should not be construed as limited to the embodiments set forth herein. Rather, these embodiments are provided so that this disclosure will be thorough and complete, and will fully convey the scope of the embodiments to those skilled in the art.

FIGS. 1 and 2 are schematic perspective and cross-sectional views, respectively, illustrating a light emitting element in accordance with an embodiment of the disclosure.

FIG. 3 is a schematic plan view illustrating a display device in accordance with an embodiment of the disclosure.

FIG. 4 is a schematic plan view illustrating a sub-pixel in accordance with an embodiment of the disclosure.

FIG. 5 is a schematic cross-sectional view taken along the line I-I′ shown in FIG. 4.

FIGS. 6 to 13 are views illustrating an apparatus for manufacturing a display device in accordance with an embodiment of the disclosure.

FIGS. 14 and 15 are views illustrating an apparatus for manufacturing a display device in accordance with another embodiment of the disclosure.

FIG. 16 is a view illustrating an apparatus for manufacturing a display device in accordance with another embodiment of the disclosure.

FIGS. 17 to 19 are flowcharts illustrating a manufacturing method of a display device in accordance with an embodiment of the disclosure.

FIGS. 20, 25, and 30 are process (or operation) plan views illustrating a manufacturing method of a display device in accordance with an embodiment of the disclosure.

FIGS. 21 to 23, 26 to 28, 31, 32, and 34 are process (or operation) plan views illustrating an apparatus for manufacturing a display device in accordance with an embodiment of the disclosure.

FIGS. 24, 29, and 33 are process (or operation) plan views illustrating a manufacturing method of a display device in accordance with an embodiment of the disclosure.

FIG. 35 is a flowchart illustrating a manufacturing method of a display device in accordance with another embodiment of the disclosure.

FIG. 36 is a schematic perspective view illustrating a manufacturing method of a display device in accordance with another embodiment of the disclosure.

### DETAILED DESCRIPTION

The embodiments described in the present specification are intended to clearly explain the concept of the present invention to a person of ordinary skill in the art; however, it is to be understood that the present invention is not limited to the embodiments described in the present specification, and it will be understood by a person of ordinary skill in the art that various modifications and changes may be made without departing from the spirit and scope of the present invention. The accompanying drawings are provided in order to allow embodiments disclosed in the present specification to be easily understood, and the shapes shown in the drawings may be exaggerated and displayed so as to aid understanding of the present invention, and the present invention is not limited to the drawings.

In the drawing figures, dimensions may be exaggerated for clarity of illustration. It is to be understood that when an element is referred to as being “between” two elements, it can be the only element between the two elements, or one or more intervening elements may also be present. Like reference numerals refer to like elements throughout.

It is to be understood that, although the terms “first,” “second,” etc. may be used herein to describe various elements, these elements are not to be limited by these terms. These terms are used to distinguish one element from another element. Thus, a “first” element discussed below could also be termed a “second” element without departing from the teachings of the disclosure. As used herein, the singular forms are intended to include the plural forms as well, unless the context clearly indicates otherwise.

It is to be further understood that the terms “includes” and/or “including,” when used in this specification, specify the presence of stated features, integers, steps, operations, elements, and/or components, but do not preclude the presence and/or addition of one or more other features, integers, steps, operations, elements, components, and/or groups thereof. Further, an expression that an element, such as a layer, region, substrate, or plate is placed “on” or “above” another element indicates not only a case in which the element is placed directly on or just above the other element but also a case in which one or more further elements are interposed between the element and the other element. Similarly, an expression that an element such as a layer, region, substrate, or plate is placed “beneath” or “below” another element indicates not only a case in which the element is placed directly beneath or just below the other element but also a case in which one or more further elements are interposed between the element and the other element.

Unless otherwise defined, all terms (including technical and scientific terms) used herein have the same meaning as commonly understood by one of ordinary skill in the art to which example embodiments of the inventive concept belong. It is to be further understood that terms, such as those defined in commonly-used dictionaries, should be interpreted as having a meaning that is consistent with their meaning in the context of the relevant art and will not be interpreted in an idealized or overly formal sense unless expressly so defined herein.

The present disclosure generally relates to a method of manufacturing a display device and an apparatus for manufacturing a display device. Herein, a method of manufacturing a display device and an apparatus for manufacturing a display device in accordance with an embodiment of the disclosure will be described with reference to the accompanying drawings.

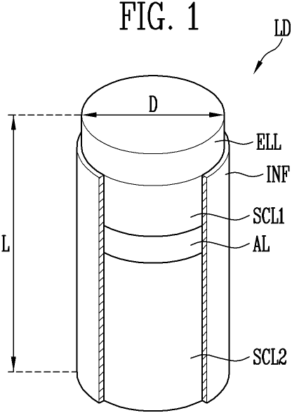

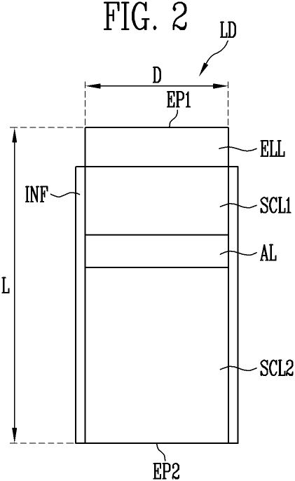

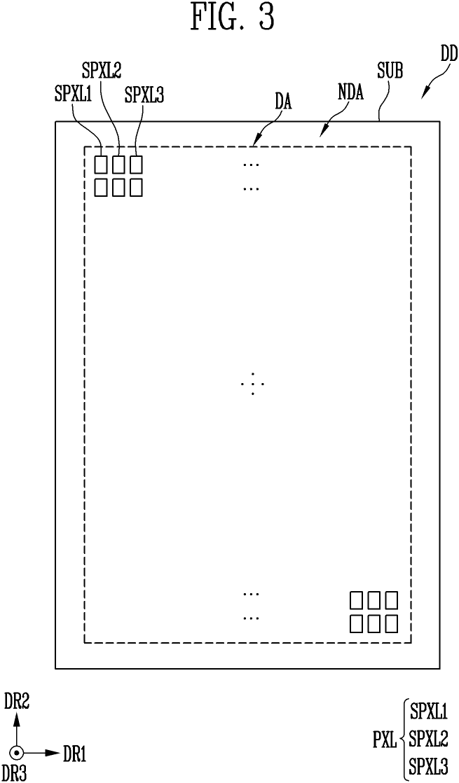

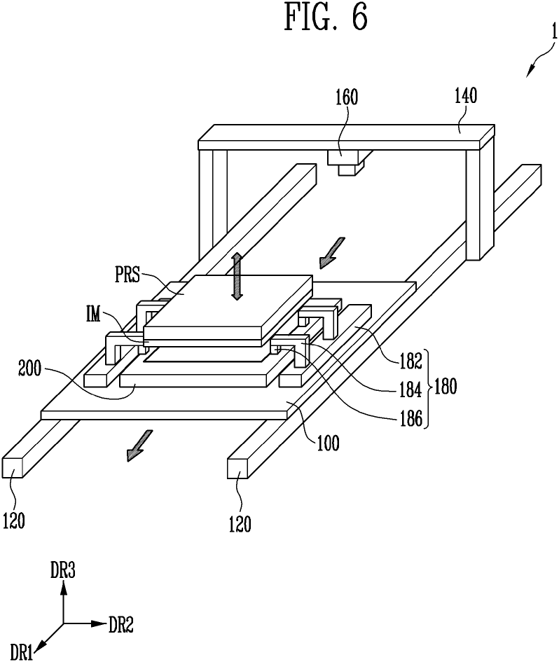

Before a manufacturing method of a display device (see DD shown in FIG. 3) and an apparatus (see 1 shown in FIG. 6) for manufacturing a display device are described, a light emitting element LD included in the display device DD in accordance with an embodiment of the disclosure will be described with reference to FIGS. 1 and 2.

FIGS. 1 and 2 are schematic perspective and cross-sectional views, respectively, illustrating a light emitting element in accordance with an embodiment of the disclosure.

Although a pillar-shaped light emitting element LD is illustrated in FIGS. 1 and 2, the kind and/or shape of the light emitting element LD is not limited thereto.

The light emitting element LD includes a second semiconductor layer SCL2, a first semiconductor layer SCL1, and an active layer AL interposed between the first and second semiconductor layers SCL1 and SCL2. For example, when assuming that an extending direction of the light emitting element LD is a length L direction, the light emitting element LD may include the first semiconductor layer SCL1, the active layer AL, and the second semiconductor layer SCL2, which are sequentially stacked along the length L direction. The light emitting element LD may further include an electrode layer ELL and an insulative film INF.

The light emitting element LD may have a pillar shape extending along one direction. The light emitting element LD may have a first end portion EP1 and a second end portion EP2. The first semiconductor layer SCL1 may be adjacent to the first end portion EP1, and the second semiconductor layer SCL2 may be adjacent to the second end portion EP2. The electrode layer ELL may be adjacent to the first end portion EP1.

The light emitting element LD may be manufactured in a pillar shape through an etching process, or the like. In this specification, the term “pillar shape” may include a rod-like shape or bar-like shape, which is relatively long in the length L direction (i.e., its aspect ratio is greater than 1), such as a cylinder or a polyprism, and the shape of a cross-section thereof is not particularly limited. For example, a length L of the light emitting element LD may be greater than a diameter D (or a width of a cross-section) of the light emitting element LD.

The light emitting element LD may have a size of nanometer scale to micrometer scale. For example, the light emitting element LD may have a diameter D (or width) in a range of nanometer scale to micrometer scale and/or a length L in a range of nanometer scale to micrometer scale. However, the size of the light emitting element LD is not limited thereto.

The first semiconductor layer SCL1 may be a first conductivity type semiconductor layer. The first semiconductor layer SCL1 is disposed on the active layer AL, and may include a semiconductor layer having a type different from a type of the second semiconductor layer SCL2. For example, the first semiconductor layer SCL1 may include a P-type semiconductor layer. In an example, the first semiconductor layer SCL1 may include at least one semiconductor material among InAlGaN, GaN, AlGaN, InGaN, AIN, and InN, and include a P-type semiconductor layer doped with a first conductivity type dopant, such as Mg. However, the material constituting the first semiconductor layer SCL1 is not limited thereto. In addition, the first semiconductor layer SCL1 may be configured with various materials.

The active layer AL is disposed between the first semiconductor layer SCL1 and the second semiconductor layer SCL2, and may be formed in a single-quantum well structure or a multi-quantum well structure. The position of the active layer AL is not limited to a specific example, and may be variously changed according to the kind of the light emitting element LD.

A clad layer doped with a conductive dopant may be formed on the top and/or the bottom of the active layer AL. For example, the clad layer may be formed as an AlGaN layer or an InAlGaN layer. In some embodiments, a material such as AlGaN or AllnGaN may be used to form the active layer AL. In addition, the active layer AL may be configured with various materials.

The second semiconductor layer SCL2 may be a second conductivity type semiconductor layer. The second semiconductor layer SCL2 is disposed on the active layer AL, and may include a semiconductor layer having a type different from the type of the first semiconductor layer SCL1. For example, the second semiconductor layer SCL2 may include an N-type semiconductor layer. For example, the second semiconductor layer SCL2 may include any semiconductor material among InAlGaN, GaN, AlGaN, InGaN, AIN, and InN, and include an N-type semiconductor layer doped with a second conductivity type dopant, such as Si, Ge or Sn. However, the material constituting the second semiconductor layer SCL2 is not limited thereto. In addition, the second semiconductor layer SCL2 may be configured with various materials.

When a voltage which is a threshold voltage or more is applied to both ends of the light emitting element LD, the light emitting element LD emits light as electron-hole pairs are combined in the active layer AL. The light emission of the light emitting element LD is controlled by using such a principle, such that the light emitting element LD may be used as a light source for various light emitting devices, including a pixel of a display device.

The insulative film INF may be disposed on a surface of the light emitting element LD. The insulative film INF may be formed on the surface of the light emitting element LD to surround an outer circumferential surface of at least the active layer AL. In addition, the insulative film INF may further surround areas of the first and second semiconductor layers SCL1 and SCL2. The insulative film INF may be formed as a single layer or a multi-layer. However, the disclosure is not limited thereto, and the insulative film INF may be configured with a plurality of layers. For example, the insulative film INF may include a first insulating layer including a first material and a second insulating layer including a second material different from the first material.

The insulative film INF may expose both end portions of the light emitting element LD, which have different polarities. For example, the insulative film INF may expose an end of each of the electrode layer ELL and the second semiconductor layer SCL2, which are respectively adjacent to the first and second end portions EP1 and EP2 of the light emitting element LD.

The insulative film INF may be configured as a single layer or a multi-layer, including any insulating material among silicon oxide (SiOₓ), silicon nitride (SiNₓ), silicon oxynitride (SiOₓN_{y}), aluminum oxide (AlOₓ), and titanium oxide (TiOₓ). However, the disclosure is not necessarily limited to the above-described example. For example, in accordance with another embodiment, the insulative film INF may be omitted.

In accordance with an embodiment, when the insulative film INF is provided to cover the surface of the light emitting element LD, particularly, the outer circumferential surface of the active layer AL, the electrical stability of the light emitting element LD can be ensured. Also, when the insulative film INF is provided on the surface of the light emitting element LD, a surface defect of the light emitting element LD may be minimized or reduced, thereby improving the lifetime and efficiency of the light emitting element LD. In addition, even when a plurality of light emitting elements LD are densely disposed, an unwanted short circuit can be prevented or substantially prevented from occurring between the light emitting elements LD.

The electrode layer ELL may be disposed on the first semiconductor layer SCL1. The electrode layer ELL may be adjacent to the first end portion EP1. The electrode layer ELL may be electrically connected to the first semiconductor layer SCL1.

A portion of the electrode layer ELL may be exposed. For example, the insulative film INF may expose a surface of the electrode layer ELL. The electrode layer ELL may be exposed in an area corresponding to the first end portion EP1. In some embodiments, a side surface of the electrode layer ELL may be exposed. For example, the insulative film INF may not cover at least a portion of the side surface of the electrode layer ELL while covering a side surface of each of the first semiconductor layer SCL1, the active layer AL, and the second semiconductor layer SCL2. Thus, the electrode layer ELL adjacent to the first end portion EP1 can be easily connected to another component. In some embodiments, the insulating layer INF may expose not only the side surface of the electrode layer ELL but also a portion of a side surface of the first semiconductor layer SCL1 and/or the second semiconductor layer SCL2.

In accordance with an embodiment, the electrode layer ELL may be an ohmic contact electrode. However, the disclosure is not necessarily limited to the above-described example. For example, the electrode layer ELL may be a Schottky contact electrode.

In accordance with an embodiment, the electrode layer ELL may include any of chromium (Cr), titanium (Ti), aluminum (Al), gold (Au), nickel (Ni), and any oxide or alloy thereof. However, the disclosure is not necessarily limited to the above-described example. In some embodiments, the electrode layer ELL may be substantially transparent. For example, the electrode layer ELL may include indium tin oxide (ITO). Accordingly, emitted light can be transmitted through the electrode layer ELL.

The structure, shape, and the like of the light emitting element LD are not limited to the above-described example. In some embodiments, the light emitting element LD may have various structures and various shapes. For example, the light emitting element LD may further include an additional electrode layer which is disposed on a surface of the second semiconductor layer SCL2 and is adjacent to the second end portion EP2.

FIG. 3 is a schematic plan view illustrating a display device in accordance with an embodiment of the disclosure.

The display device DD is configured to emit light. Referring to FIG. 3, the display device DD may include a substrate SUB and pixels PXL arranged on the substrate SUB. Although not shown in the drawing, the display device DD may further include a driving circuit (e.g., a scan driver and a data driver) for driving the pixels PXL, lines, and pads.

The display device DD may include a display area DA and a non-display area NDA. The non-display area NDA may refer to an area except the display area DA. In an embodiment, the non-display area NDA may surround at least a portion of the display area DA.

The substrate SUB may constitute a base member of the display device DD. The substrate SUB may be a rigid or flexible substrate or film. For example, the substrate SUB may be a rigid substrate made of glass or tempered glass, a flexible substrate (or thin film) made of a plastic or metal material, or at least one insulating layer. The material and/or property of the substrate SUB is not particularly limited. In an embodiment, the substrate SUB may be substantially transparent. The term “substantially transparent” may mean that light can be transmitted with a certain transmittance (e.g., a predetermined transmittance) or more. In another embodiment, the substrate SUB may be translucent or opaque. Also, the substrate SUB may include a reflective material in some embodiments.

The display area DA may refer to an area in which the pixels PXL are disposed. The non-display area NDA may refer to an area in which the pixels PXL are not disposed. The driving circuit, the lines, and the pads, which are connected to the pixels PXL of the display area DA, may be disposed in the non-display area NDA.

In an example, the pixels PXL may be arranged according to a stripe arrangement structure, a PENTILE^{®} arrangement structure, or the like. However, the disclosure is not limited thereto, and various embodiments may be applied in the disclosure.

In accordance with an embodiment, the pixel PXL may include a first sub-pixel SPXL1, a second sub-pixel SPXL2, and a third sub-pixel SPXL3. Each of the first sub-pixel SPXL1, the second sub-pixel SPXL2, and the third sub-pixel SPXL3 may be a sub-pixel. At least one first sub-pixel SPXL1, at least one second sub-pixel SPXL2, and at least one third sub-pixel SPXL3 may constitute one pixel unit configured to emit lights of various colors.

For example, each of the first sub-pixel SPXL1, the second sub-pixel SPXL2, and the third sub-pixel SPXL3 may emit light of a certain color (e.g., a predetermined color). For example, the first sub-pixel SPXL1 may be a red pixel emitting light of red (e.g., a first color), the second sub-pixel SPXL2 may be a green pixel emitting light of green (e.g., a second color), and the third sub-pixel SPXL3 may be a blue pixel emitting light of blue (e.g., a third color). However, the color, kind, and/or number of first, second, and third sub-pixels SPXL1, SPXL2, and SPXL3 constituting each pixel unit are not limited to a specific example.

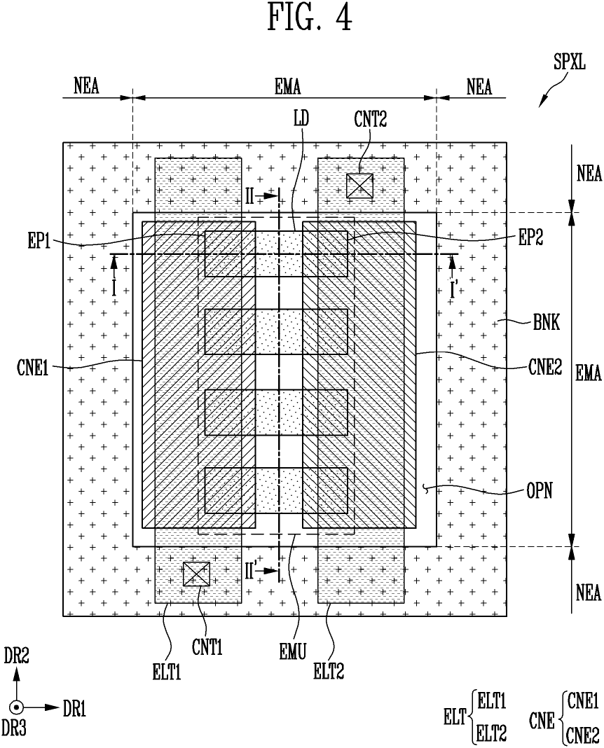

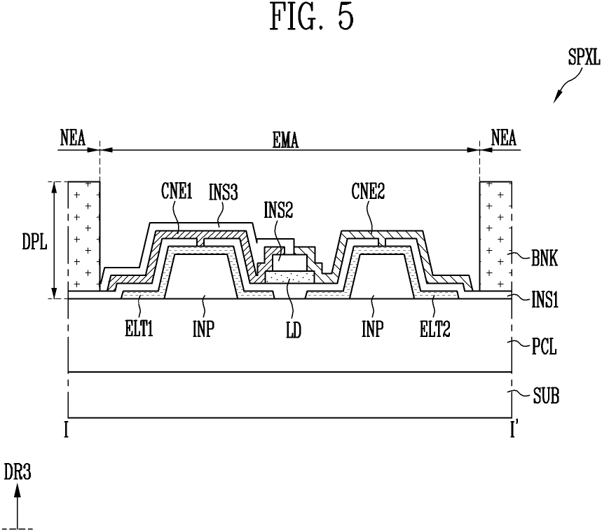

Herein, a sub-pixel SPXL in accordance with an embodiment of the disclosure will be described with reference to FIGS. 4 and 5.

FIG. 4 is a schematic plan view illustrating a sub-pixel in accordance with an embodiment of the disclosure. For example, the sub-pixel SPXL shown in FIG. 4 may be one of the above-described first to third sub-pixels SPXL1, SPXL2, and SPXL3.

Referring to FIG. 4, the sub-pixel SPXL (or the display device DD) may include an emission area EMA and a non-emission area NEA. The sub-pixel SPXL may include an alignment electrode ELT, light emitting elements LD, a bank BNK, a first contact part CNT1, a second contact part CNT2, and a contact electrode CNE. In some embodiments, the alignment electrode ELT may include a first electrode ELT1 and a second electrode ELT2. The contact electrode CNE may include a first contact electrode CNE1 and a second contact electrode CNE2.

The emission area EMA may be an area in which the light emitting elements LD are provided, to emit light. The non-emission area NEA may be an area in which the light emitting elements LD are not disposed, and the light is not emitted.

The emission area EMA may overlap with an opening OPN defined by the bank BNK when viewed on a plane. The light emitting elements LD may be disposed in the emission area EMA.

The light emitting elements LD may not be disposed in the non-emission area NEA. A portion of the non-emission area NEA may overlap with the bank BNK when viewed on a plane.

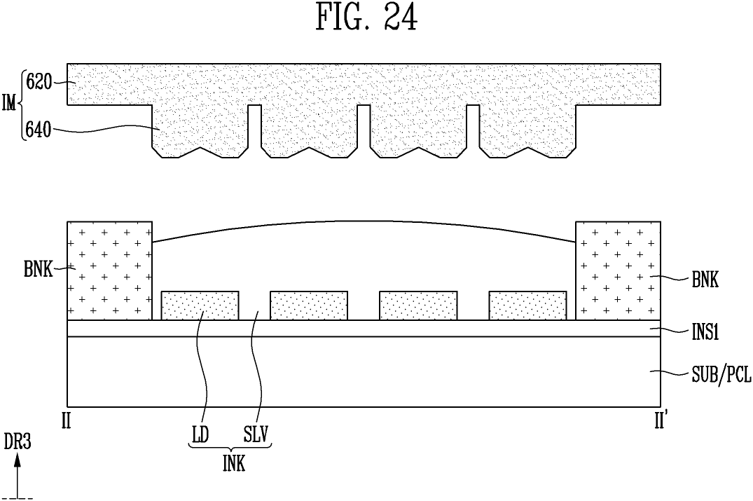

The bank BNK may form (or provide) the opening OPN. For example, the bank BNK may have a shape protruding in a thickness direction of the substrate SUB (e.g., a third direction DR3), and have a shape surrounding an area (e.g., a predetermined area). Accordingly, the opening OPN in which the bank BNK is not disposed can be formed. In some embodiments, the bank BNK may form a space in which a fluid can be accommodated. For example, an ink (see INK shown in FIG. 24) including the light emitting elements LD may be provided in the space in which the fluid can be accommodated, thereby disposing the light emitting elements LD in the opening OPN.

The bank BNK may define the emission area EMA and the non-emission area NEA. The bank BNK may surround at least a portion of the emission area EMA when viewed on a plane. For example, an area in which the bank BNK is disposed may be the non-emission area NEA. An area in which the light emitting elements LD are disposed as an area in which the bank BNK is not disposed may be the emission area EMA.

At least a portion of the light emitting element LD may be disposed between the first electrode ELT1 and the second electrode ELT2. The light emitting element LD may be aligned between the first electrode ELT1 and the second electrode ELT2. The light emitting elements LD may form (or constitute) a light emitting unit EMU. The light emitting unit EMU may refer to a unit including adjacent light emitting elements LD.

The first electrode ELT1 and the second electrode ELT2 may be spaced apart from each other. For example, the first electrode ELT1 and the second electrode ELT2 may be spaced apart from each other along a first direction DR1 in the emission area EMA, and each of the first electrode ELT1 and the second electrode ELT2 may extend along a second direction DR2.

In some embodiments, the first electrode ELT1 may be a first alignment electrode, and the second electrode ELT2 may be a second alignment electrode.

The first electrode ELT1 and the second electrode ELT2 may be respectively supplied with a first alignment signal and a second alignment signal in a process of aligning the light emitting elements LD. The first alignment signal and the second alignment signal may have different waveforms, different potentials, and/or different phases. Accordingly, an electric field is formed between the first electrode ELT1 and the second electrode ELT2, such that the light emitting elements LD can be aligned between the first electrode ELT1 and the second electrode ELT2.

The first electrode ELT1 may be electrically connected to a circuit element (e.g., a driving transistor) through the first contact part CNT1. In some embodiments, the first electrode ELT1 may provide an anode signal. The first electrode ELT1 may provide the first alignment signal.

The second electrode ELT2 may be electrically connected to a power line through the second contact part CNT2. In some embodiments, the second electrode ELT2 may provide a cathode signal. The second electrode ELT2 may provide the second alignment signal.

Each of the first and second electrodes ELT1 and ELT2 may be configured as a single layer or a multi-layer. For example, each of the first and second electrodes ELT1 and ELT2 may include at least one reflective electrode layer including a reflective conductive material, and selectively further include at least one transparent electrode layer and/or at least one conductive capping layer.

The light emitting elements LD may be aligned between the first electrode ELT1 and the second electrode ELT2. For example, the light emitting elements LD may be aligned and/or connected in parallel between the first electrode ELT1 and the second electrode ELT2.

In an embodiment, the light emitting elements LD may be aligned in the second direction DR2 between the first electrode ELT1 and ELT2, to be electrically connected to the first and second electrodes ELT1 and ELT2.

The first end portion EP1 of the light emitting element LD may be disposed adjacent to the first electrode ELT1, and the second end portion EP2 may be disposed adjacent to the second electrode ELT2. The first end portion EP1 may or may not overlap with the first electrode ELT1. The second end portion EP2 may or may not overlap with the second electrode ELT2.

In an embodiment, the first end portion EP1 of each of the light emitting elements LD may be electrically connected to the first electrode ELT1 through the first contact electrode CNE1. In another embodiment, the first end portion EP1 of each of the light emitting elements LD may be directly connected to the first electrode ELT1. In still another embodiment, the first end portion EP1 of each of the light emitting elements LD is electrically connected to only the first contact electrode CNE1, and may not be connected to the first electrode ELT1.

Similarly, the second end portion EP2 of each of the light emitting elements LD may be electrically connected to the second electrode ELT2 through the second contact electrode CNE2. In another embodiment, the second end portion EP2 of each of the light emitting elements LD may be directly connected to the second electrode ELT2. In still another embodiment, the second end portion EP2 of each of the light emitting elements LD is electrically connected to only the second contact electrode CNE2, and may not be connected to the second electrode ELT2.

The first contact electrode CNE1 and the second contact electrode CNE2 may be respectively disposed on the first end portions EP1 and the second end portions EP2 of the light emitting elements LD.

The first contact electrode CNE1 may be disposed on the first end portions EP1 of the light emitting elements LD to be electrically connected to the first end portions EP1. In an embodiment, the first contact electrode CNE1 may be disposed on the first electrode ELT1 to be electrically connected to the first electrode ELT1. The first end portions EP1 of the light emitting elements LD may be connected to the first electrode ELT1 through the first contact electrode CNE1.

The second contact electrode CNE2 may be disposed on the second end portions EP2 of the light emitting elements LD to be electrically connected to the second end portions EP2. In an embodiment, the second contact electrode CNE2 may be disposed on the second electrode ELT2 to be electrically connected to the second electrode ELT2. The second end portions EP2 of the light emitting elements LD may be connected to the second electrode ELT2 through the second contact electrode CNE2.

The structure of the sub-pixel SPXL in accordance with embodiments of the disclosure is not necessarily limited to the above-described example, and the sub-pixel SPXL may include various appropriate structures.

FIG. 5 is a schematic cross-sectional view taken along the line I-I′ shown in FIG. 4. FIG. 5 may be a schematic cross-sectional view illustrating a sub-pixel SPXL in accordance with an embodiment of the disclosure.

Referring to FIG. 5, the sub-pixel SPXL may include a substrate SUB, a pixel circuit layer PCL, and a display element layer DPL.

The substrate SUB may provide an area in which the pixel circuit layer PCL and the display element layer DPL are disposed. The substrate SUB may be a base surface of the sub-pixel SPXL.

The pixel circuit layer PCL may be disposed on the substrate SUB. The pixel circuit layer PCL may include a transistor and a plurality of insulating layers. The transistor may be a thin film transistor. In some embodiments, the transistor may be a driving transistor. Any of the plurality of insulating layers may be disposed on the transistor. The structure of the pixel circuit layer PCL is not limited to a specific example, and the pixel circuit layer PCL may include various structures.

The display element layer DPL may be disposed on the pixel circuit layer PCL. The display element layer DPL may include an insulating pattern INP, the first electrode ELT1, the second electrode ELT2, a first insulating layer INS1, the bank BNK, the light emitting element LD, a second insulating layer INS2, the first contact electrode CNE1, a third insulating layer INS3, and the second contact electrode CNE2.

The insulating pattern INP may protrude in the thickness direction of the substrate SUB (e.g., the third direction DR3). The insulating pattern INP may provide a surface on which the first electrode ELT1 and the second electrode ELT2 are arranged.

The first electrode ELT1 and the second electrode ELT2 may be disposed on the pixel circuit layer PCL and the insulating pattern INP. As described above, the first electrode ELT1 and the second electrode ELT2 may be alignment electrodes for aligning the light emitting element LD.

A portion of each of the first electrode ELT1 and the second electrode ELT2 may be disposed on the insulating pattern INP, to form a reflective wall. Accordingly, the light emission efficiency of the display device DD can be improved.

In some embodiments, the first electrode ELT1 may be electrically connected to the light emitting element LD through the first contact electrode CNE1. The second electrode ELT2 may be electrically connected to the light emitting element LD through the second contact electrode CNE2.

The first insulating layer INS1 may be disposed on the pixel circuit layer PCL, the first electrode ELT1, and the second electrode ELT2. The first insulating layer INS1 may stabilize connection between electrode components, and reduce external influence. The first insulating layer INS1 may include any of silicon oxide (SiOₓ), silicon nitride (SiNₓ), silicon oxynitride (SiOₓN_{y}), aluminum oxide (AlOₓ), and titanium oxide (TiOₓ). However, the disclosure is not limited to the above-described example.

The bank BNK may protrude in the thickness of the substrate SUB (e.g., the third direction DR3). The bank BNK may include an organic material, such as acrylic resin, epoxy resin, phenolic resin, polyamide resin, polyimide resin, unsaturated polyester resin, poly-phenylene ether resin, poly-phenylene sulfide resin, or benzocyclobutene (BCB). However, the disclosure is not necessarily limited thereto, and the bank BNK may include various kinds of inorganic insulating materials, including silicon oxide (SiOₓ), silicon nitride (SiNₓ), silicon oxynitride (SiOₓN_{y}), aluminum nitride (AINₓ), aluminum oxide (AlOₓ), zirconium oxide (ZrOₓ), hafnium oxide (HfOₓ), and titanium oxide (TiOₓ).

The light emitting element LD may be disposed on the first insulating layer INS1. In some embodiments, the light emitting element LD may emit light, based on an electrical signal provided from the first contact electrode CNE1 and the second contact electrode CNE2.

The light emitting element LD may be disposed in an area surrounded by the bank BNK. Accordingly, an emission area EMA can be defined as the area in which the light emitting element LD is disposed. The light emitting element LD may be disposed between adjacent insulating patterns INP.

The second insulating layer INS2 may be disposed on the light emitting element LD. The second insulating layer INS2 may cover the active layer AL of the light emitting element LD.

The second insulating layer INS2 may expose at least a portion of the light emitting element LD. For example, the second insulating layer INS2 may not cover the first end portion EP1 and the second end portion EP2 of the light emitting element LD. Accordingly, the first end portion EP1 and the second end portion of the light emitting element LD may be exposed, and be electrically connected respectively to the first contact electrode CNE1 and the second contact electrode CNE2.

When the second insulating layer INS2 is disposed on the light emitting elements LD after the light emitting elements LD are completely aligned, the light emitting elements LD can be prevented or substantially prevented from being separated from positions at which the light emitting elements LD are aligned.

The second insulating layer INS2 may be configured as a single layer or a multi-layer, and may include various kinds of inorganic insulating materials, including silicon oxide (SiOₓ), silicon nitride (SiNₓ), silicon oxynitride (SiOₓN_{y}), aluminum nitride (AINₓ), aluminum oxide (AlOₓ), zirconium oxide (ZrOₓ), hafnium oxide (HfOₓ), and titanium oxide (TiOₓ). However, the disclosure is not limited to the above-described example.

The first contact electrode CNE1 and the second contact electrode CNE2 may be disposed on the first insulating layer INS1. The first contact electrode CNE1 may be electrically connected to the first end portion EP1 of the light emitting element LD. The second contact electrode CNE2 may be electrically connected to the second end portion EP2 of the light emitting element LD.

The first contact electrode CNE1 may be electrically connected to the first electrode ELT1 through a contact hole penetrating the first insulating layer INS1, and the second contact electrode CNE2 may be electrically connected to the second electrode ELT2 through a contact hole penetrating the first insulating layer INS1.

The first contact electrode CNE1 and the second contact electrode CNE2 may include a conductive material. For example, the first contact electrode CNE1 and the second contact electrode CNE2 may include a transparent conductive material including any of indium tin oxide (ITO), indium zinc oxide (IZO), and indium tin zinc oxide (ITZO). However, the disclosure is not necessarily limited to the above-described example.

The third insulating layer INS3 may be disposed on the first insulating layer INS1, the first contact electrode CNE1, the second contact electrode CNE2, and the second insulating layer INS2. The third insulating layer INS3 may be configured as a single layer or a multi-layer, and may include various kinds of inorganic insulating materials, including silicon oxide (SiOₓ), silicon nitride (SiNₓ), silicon oxynitride (SiOₓN_{y}), aluminum nitride (AINₓ), aluminum oxide (AlOₓ), zirconium oxide (ZrOₓ), hafnium oxide (HfOₓ), and titanium oxide (TiOₓ).

The structure of the sub-pixel SPXL in accordance with embodiments of the disclosure is not necessarily limited to the above-described example. For example, the sub-pixel SPXL may further include an additional bank disposed on the bank BNK. Also, the sub-pixel SPXL may further include a color conversion layer including a quantum dot configured to change a wavelength of light emitted from the light emitting element LD. For example, the color conversion layer may be disposed in the same layer as the display element layer DPL, or be disposed on the display element layer DPL. Also, the sub-pixel SPXL may further include a color filter layer which allows light in one wavelength band to be selectively transmitted therethrough.

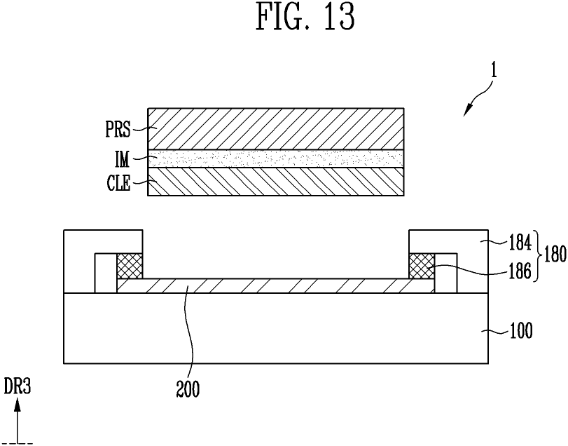

Herein, an apparatus 1 for manufacturing a display device in accordance with an embodiment of the disclosure will be described with reference to FIGS. 6 to 16. In FIGS. 6 to 16, descriptions of portions overlapping with those described above may be simplified or may not be repeated.

First, an apparatus 1 for manufacturing a display device in accordance with an embodiment of the disclosure will be described with reference to FIGS. 6 to 13. FIGS. 6 to 13 are views illustrating an apparatus for manufacturing a display device in accordance with an embodiment of the disclosure.

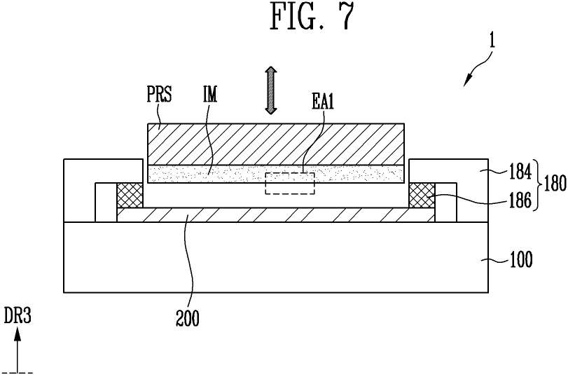

FIG. 6 is a schematic perspective view illustrating the apparatus 1 for manufacturing a display device in accordance with an embodiment of the disclosure. FIG. 7 is a schematic cross-sectional view illustrating the apparatus 1 for manufacturing a display device in accordance with an embodiment of the disclosure.

Referring to FIGS. 6 and 7, the apparatus 1 may include a stage 100, a rail 120, a printer support part 140, an ink printer 160, a probe device 180, a press PRS, and a mold IM.

In accordance with an embodiment, the apparatus 1 may perform a process on a substrate 200 for manufacturing a display device, thereby providing (or manufacturing) the display device DD in accordance with an embodiment of the disclosure. In some embodiments, the substrate 200 may be inclusively designated as a substrate SUB for convenience. A light emitting element LD and the like may be disposed on the substrate 200, such that a pixel PXL (or sub-pixel SPXL) is formed. Herein, for convenience of description, the substrate 200 is designated as a manufacturing substrate 200.

The stage 100 may support the manufacturing substrate 200. The stage 100 may be disposed on the rail 120. The stage 100 may provide an area in which the manufacturing substrate 200 is disposed. The manufacturing substrate 200 may be loaded on or unloaded from the stage 100. In some embodiments, the stage 100 may include a rigid material, but the disclosure is not necessarily limited thereto.

The stage 100 may change a position of the manufacturing substrate 200. For example, a position of the stage 100 may be changed along the rail 120.

The rail 120 may be a path through which the stage 100 is moved. Accordingly, the manufacturing substrate 200 may be moved along the rail 120. The rail 120 may extend a process direction on the manufacturing substrate 200 (e.g., the first direction DR1).

The printer support part 140 may be disposed at a position with respect to the process direction, to be connected (or coupled) to the ink printer 160. In some embodiments, the printer support part 140 may be moved along the first direction DR1. Accordingly, the ink printer 160 may be moved by the printer support part 140. In some embodiments, the printer support part 140 may be a gantry.

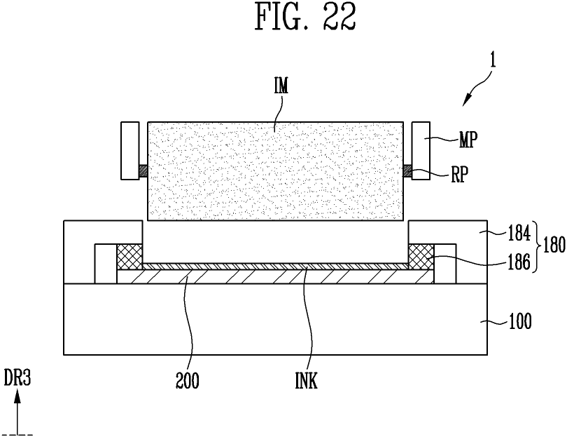

The ink printer 160 may be connected to the printer support part 140, to supply (or provide) an ink (see INK shown in FIG. 22) including the light emitting element LD. For example, when the manufacturing substrate 200 is disposed to be adjacent to the ink printer 160, the ink printer 160 may discharge the ink INK. Accordingly, the ink INK can be supplied onto the manufacturing substrate 200.

The ink printer 160 may be moved in the first direction DR1 and/or the second direction DR2. For example, the ink printer 160 may be coupled to the printer support part 140 to be moved in the first direction DR1 and/or the second direction DR2. The ink printer 160 may be moved along the first direction DR1 as the printer support part 140 is moved in the first direction DR1.

In some embodiments, the ink printer 160 may be designated as a dispenser.

The probe device 180 may be disposed on the stage 100. The probe device 180 may be disposed adjacent to a side of the manufacturing substrate 200. In some embodiments, the probe device 180 may be disposed at each of a first side and a second side of the manufacturing substrate 200.

In some embodiments, the probe device 180 may be designated as a probe module. The probe device 180 may include a probe support part 182, a probe moving part 184, and a probe unit 186.

The probe device 180 may supply (or provide) an electrical signal to the manufacturing substrate 200. The probe device 180 may form an electric field in the manufacturing substrate 200. For example, the probe unit 186 may provide an electrical signal onto a pad formed in the manufacturing substrate 200, and the provided signal may be provided to an alignment electrode ELT, such that an electric field is formed in an area in which the light emitting element LD is aligned.

The probe support part 182 may be disposed on the stage 100. The probe support part 182 may provide an area in which the probe moving part 184 and the probe unit 186 are disposed. In some embodiments, the probe support part 182 may be disposed at each of the first side and the second side of the manufacturing substrate 200. However, the area in which the probe support parts 182 are disposed and the number of the probe support parts 182 may be appropriately changed.

The probe moving part 184 may be disposed on the probe support part 182. The probe moving part 184 may change a position of the probe unit 186. For example, the probe moving part 184 may move the probe unit 186 in a direction parallel to the first direction DR1. The probe moving part 184 may move the probe unit 186 in a direction parallel to the second direction DR2. The probe moving part 184 may move the probe unit 186 in a direction parallel to the third direction DR3. Accordingly, the position of the probe unit 186 configured to supply an electrical signal to the manufacturing substrate 200 can be appropriately controlled. In some embodiments, the position of the probe unit 186 may be changed to correspond to a position of the pad of the manufacturing substrate 200.

The probe unit 186 may be connected to the probe moving part 184. The probe unit 186 may supply an electrical signal such that an electric field is formed in the manufacturing substrate 200. For example, the probe unit 186 may be moved in the first to third directions DR1 to DR3 by the probe moving part 184, and be in contact with the pad of the manufacturing substrate 200.

In some embodiments, the probe unit 186 may be provided in plural, and be disposed at the first side and/or the second side of the manufacturing substrate 200. However, the area in which the probe units 186 are disposed and the number of the probe units 186 may be appropriately changed.

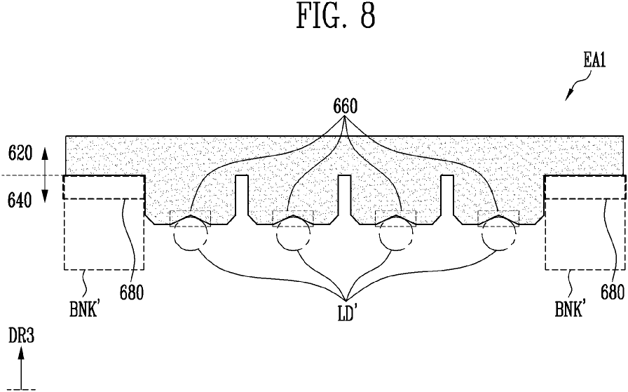

The press PRS may be disposed at a side of the mold IM. In some embodiments, the press PRS may be in contact with the mold IM. For example, the press PRS may be in contact with a base part (see 620 shown in FIG. 8) of the mold IM. In some embodiments, the press PRS may be disposed at a position spaced apart from the ink printer 160 in the process direction (e.g., the first direction DR1).

A movement of the press PRS may correspond to a movement of the mold IM. The press PRS may move the mold IM. For example, as the press PRS is moved in a direction parallel to the third direction DR3, the press PRS may move a position of the mold IM in the direction parallel to the third direction DR3. In some embodiments, the direction in which the press PRS is moved may be parallel to a gravity direction.

The press PRS may apply a pressure to the mold IM. For example, the press PRS may push the mold IM in a direction, and, accordingly, pressure can be applied to an object (e.g., the light emitting element LD) in contact with the mold IM. The press PRS may be configured to apply, to the mold IM, a pressure toward the manufacturing substrate 200 from the mold IM. For example, the press PRS may be configured to apply, to the mold IM, a pressure toward the stage 100 from the mold IM.

The press PRS may include a hard material, thereby having a property suitable for applying a pressure to the mold IM. However, the disclosure is not necessarily limited to the above-described example.

The mold IM may be disposed on the press PRS. For example, the mold IM may be in contact with a surface of the press PRS. The mold IM may be disposed on the press PRS such that a protrusion part (see 640 shown in FIG. 8) faces the manufacturing substrate 200.

The mold IM may be moved to be adjacent onto the manufacturing substrate 200 (or the stage 100), and be moved to be spaced apart from the manufacturing substrate 200 (or the stage 100). For example, the mold IM may be moved along a direction parallel to a thickness direction of the manufacturing substrate 200 by the press PRS. In some embodiments, the mold IM may be moved along the gravity direction, to push an object (e.g., the light emitting element LD) on the manufacturing substrate 200.

In accordance with an embodiment, the mold IM may have an elastic property. Accordingly, when the mold IM applies a pressure to the light emitting element LD, damage of the light emitting element LD can be prevented or substantially prevented while changing a pose of the light emitting element LD. For example, the mold IM may include an elastomer. However, the disclosure is not limited to the above-described example. In some embodiments, the mold IM may include a flexible polymer film. In addition, the mold IM may include various materials.

The mold IM may include a plurality of groove patterns. In accordance with an embodiment, the mold IM may include a structure patterned on a micrometer scale or a nanometer scale. For example, the mold IM may include a template in which a plurality of grooves are formed of one material. In some embodiments, each of the plurality of groove patterns may correspond to an arrangement position and an arrangement pose of the light emitting element LD aligned on the substrate SUB.

A shape of the mold IM associated with this will be described in conjunction with FIGS. 8 to 12.

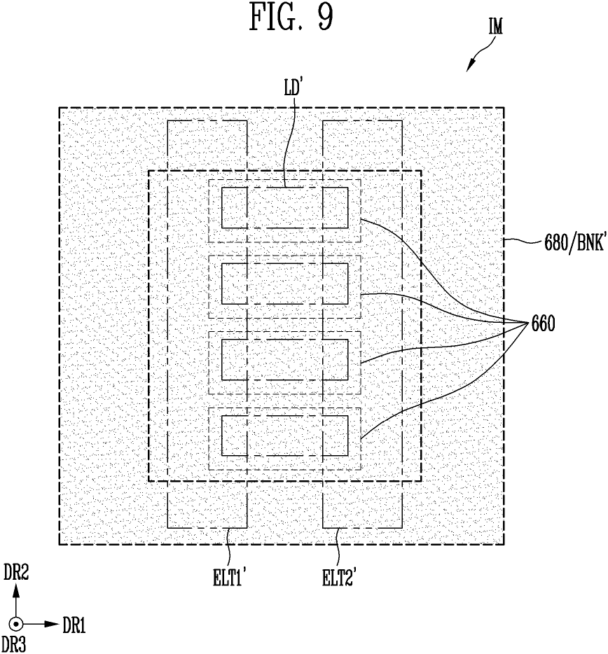

FIGS. 8 to 12 are schematic views illustrating a shape of the mold in accordance with an embodiment of the disclosure. FIGS. 8 and 10 to 12 are schematic cross-sectional views illustrating the shape of the mold IM in accordance with an embodiment of the disclosure. FIG. 9 is a schematic plan view illustrating the shape of the mold IM in accordance with an embodiment of the disclosure.

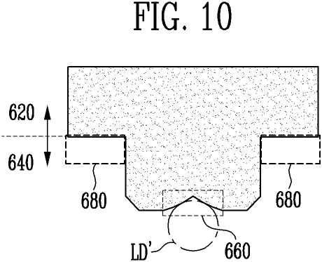

FIG. 8 is a schematic enlarged view of an area “EA1” shown in FIG. 7. FIG. 9 is a schematic plan view illustrating a structure of the mold IM corresponding to an area of the sub-pixel SPXL described above with reference to FIG. 4. FIGS. 10 to 12 are schematic cross-sectional views illustrating shapes of the mold IM in accordance with some modified embodiments of the disclosure.

Referring to FIGS. 8 and 9, the mold IM may include a base part 620 and a protrusion part 640. In accordance with an embodiment, the mold IM may include a light emitting element area 660 and a mold movement restriction area 680. In accordance with an embodiment, the protrusion part 640 may be provided in plural, to be disposed on the base part 620. In some embodiments, the light emitting element area 660 may be designated as a groove area.

For convenience of descriptions, in FIG. 9, the mold movement restriction area 680 is indicated by a dotted line thicker than a dotted line of the light emitting element area 660. In FIG. 9, when a process of aligning a light emitting element LD by using the mold IM is performed, each of relative positions of a first electrode ELT1, a second electrode ELT2, the light emitting element LD, and a bank BNK is indicated by a predetermined line. For example, the position of the light emitting element LD is indicated by an alternated long and short dash line, and each of the positions of the first electrode ELT1 and the second electrode ELT2 may be indicated by an alternate long and two short dashes line. In addition, the position of the bank BNK may be indicated to correspond to the mold movement restriction area 680.

In some embodiments, a plurality of grooves (e.g., groove patterns) may be formed in the mold IM. The formed groove may refer to one or more of a groove formed between the protrusion parts 640, the light emitting element area 660 formed in the protrusion part 640, and the mold movement restriction area 680.

The base part 620 may be a base surface on which the protrusion part 640 is disposed. The protrusion part 640 may be disposed on the base part 620.

The protrusion part 640 may not be disposed in a partial area of the base part 620, and, accordingly, a portion of the base part 620 may be exposed. In some embodiments, the partial area in which the protrusion part 640 is not disposed on the base part 620 may be provided (or formed) as the mold movement restriction area 680.

In accordance with an embodiment, when the process of aligning the light emitting element LD by using the mold IM is performed, the mold movement restriction area 680 may overlap with an area BNK′ in which the bank BNK is disposed, when viewed on a plane. The bank BNK having a protruding shape can prevent or substantially prevent the mold IM from excessively becoming adjacent to the manufacturing substrate 200. Accordingly, damage of the light emitting element LD can be prevented or substantially prevented, and process performance can be improved.

The protrusion part 640 may be disposed on a surface of the base part 620. The protrusion part 640 may protrude in a thickness direction of the base part 620 (e.g., a direction parallel to the third direction DR3). In some embodiments, the protrusion part 640 may not be disposed in the mold movement restriction area 680.

The protrusion part 640 (or the mold IM) may include the light emitting element area 660. For example, each of the protrusion parts 640 may further include a groove, so that the light emitting element area 660 defined to be recessed in a direction is formed in each of the protrusion parts 640. The light emitting element area 660 may be provided in plural, to respectively correspond to areas of light emitting elements LD to be aligned (or disposed).

In accordance with an embodiment, the light emitting element area 660 may extend in a same direction as a direction in which each of the light emitting elements LD extend (e.g., the first direction DR1 in FIG. 9). The light emitting element area 660 may extend in a direction in which the first electrode ELT1 and the second electrode ELT2 are spaced apart from each other (e.g., the first direction DR1 in FIG. 9).

Accordingly, when the mold IM pushes the light emitting element LD, a pose, or orientation, of the light emitting element LD may be changed to correspond to the light emitting element area 660. For example, when the mold IM pushes the light emitting element LD, the light emitting element LD may be rotated to correspond to the light emitting element area 660. In addition, the light emitting elements LD may be arranged to generally face an area ELT2′ in which the second electrode ELT2 is disposed from an area ELT1′ in which the first electrode ELT1 is disposed.

In accordance with an embodiment, when the process of aligning the light emitting element LD by using the mold IM is performed, the light emitting element area 660 may overlap with each area LD′ in which the light emitting element LD is disposed, when viewed on a plane. Since the light emitting elements LD are arranged to respectively correspond to the plurality of groove patterns of the mold IM (e.g., the light emitting element areas 660), the light emitting elements can be easily disposed to correspond to a desired position of a user.

In addition, since the light emitting element area 660 corresponds to an area in which each individual light emitting element LD is aligned, a phenomenon in which the light emitting elements LD are abnormally operated as the light emitting elements LD are electrically adjacent to each other (e.g., an agglomeration phenomenon of the light emitting elements LD) can be prevented or substantially prevented. That is, the mold IM applies a pressure to the light emitting elements LD, such that the positions at which the light emitting elements LD are aligned can respectively correspond to the light emitting element areas 660.

Consequently, a desired arrangement of the user can be easily implemented, and thus process performance can be improved. In addition, since an alignment degree of the light emitting element LD is improved, a ratio of light emitting elements LD which are normally operated is remarkably increased, and, accordingly, the light emission efficiency of the light emitting elements LD and the light emission efficiency of the display device DD can be improved.

In accordance with an embodiment, the shape of the protrusion part 640 for forming the light emitting element area 660 may be variously modified.

For example, referring to FIG. 8, the protrusion part 640 may have a groove having a triangular shape in a cross-section. A groove having a triangular prism shape may be formed in the protrusion part 640. The groove for forming the light emitting element area 660 may have a size corresponding to a size of a bottom surface of the light emitting element LD in the area LD′ in which the light emitting element LD is disposed. In accordance with an embodiment, a process for forming the light emitting element area 660 can be simplified, and the alignment of the light emitting element LD can be more thoroughly made since a groove corresponding to the size of the light emitting element LD in the area LD′ in which the light emitting element LD is disposed is formed.

Next, referring to FIG. 10, a protrusion part 640 in accordance with an embodiment of the disclosure may have a valley shape which has a curved surface and is sharply recessed in a cross-section. Accordingly, the light emitting element area 660 may be generally defined along the curved surface. A pressure may be applied to the light emitting element LD along the curved surface in the area LD′ in which the light emitting element LD is disposed.

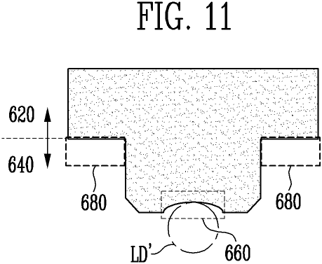

Next, referring to FIG. 11, a protrusion part 640 in accordance with an embodiment of the disclosure may have a curved shape which corresponds to the size of the bottom surface of the light emitting element LD in the area LD′ in which the light emitting element LD is disposed and is gently curved in a cross-section. For example, the light emitting element area 660 may have a shape corresponding to the bottom surface of the light emitting element LD in the area LD′ in which the light emitting element LD is disposed at a surface facing the light emitting element LD in the area LD′ in which the light emitting element LD is disposed.

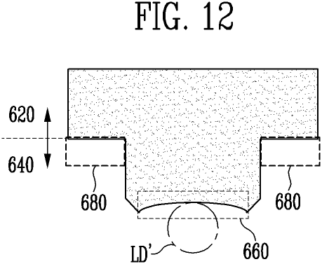

Next, referring to FIG. 12, a protrusion part 640 in accordance with an embodiment of the disclosure may have a curved shape which is greater than the size of the bottom surface of the light emitting element LD in the area LD′ in which the light emitting element LD is disposed and is generally gently curved in a cross-section. For example, the light emitting element area 660 may have a gently curved shape at a surface facing the light emitting element LD in the area LD′ in which the light emitting element LD is disposed.

However, the shapes of the protrusion part 640 and the light emitting element area 660 are not necessarily limited to the above-described examples, and may be appropriately modified within a range in which technical features of the disclosure are maintained. For example, a portion of an outer surface of the protrusion part 640 may have a curved surface or a flat surface. In some embodiments, the protrusion part 640 may include a gently curved area or a sharp apex area.

The apparatus 1 in accordance with an embodiment of the disclosure may include a cleaner CLE. The cleaner CLE may be configured to clean the mold IM. The cleaner CLE may remove the light emitting element LD and the ink INK, which are provided on the mold IM after the process of aligning the light emitting element LD is performed (or while the process is performed). Accordingly, when a subsequent process using the mold IM is performed, the ink INK can be prevented or substantially prevented from being excessively supplied, and process precision can be improved. In some embodiments, when cleaner CLE cleans the mold IM, the cleaner CLE may be disposed adjacent to an outer surface of the mold IM (e.g., a surface at which the protrusion part 640 is disposed) for efficiently removing the ink INK remaining on the mold IM.

In some embodiments, the cleaner CLE may include a drain device configured to absorb the ink INK. Also, in some embodiments, the cleaner CLE may be configured to spray a cleaning solution for cleaning a surface of the mold IM, on which the ink INK remains. Also, in some embodiments, the cleaner CLE may include a drying device for drying the surface of the mold IM, on which the ink INK remains. However, the disclosure is not necessarily limited to the above-described examples.

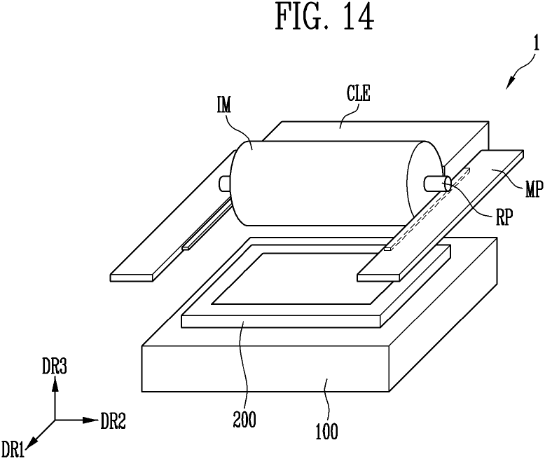

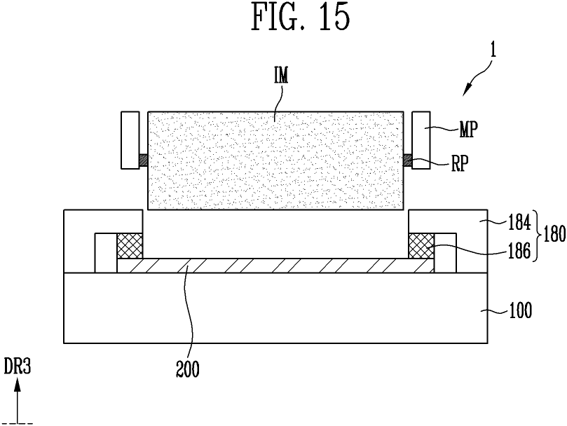

Next, an apparatus 1 for manufacturing a display device in accordance with another embodiment of the disclosure will be described with reference to FIGS. 14 and 15. FIGS. 14 and 15 are views illustrating an apparatus for manufacturing a display device in accordance with a second embodiment of the disclosure.

In FIGS. 14 and 15, descriptions of portions overlapping with those described above may be simplified or may not be repeated, and portions different from those of the above-described embodiment will be mainly described.

In FIG. 14, for convenience of descriptions, a stage 100 and a manufacturing substrate 200 are illustrated, and illustration of other components of the apparatus 1 is omitted.

Referring to FIGS. 14 and 15, the apparatus 1 in accordance with another embodiment of the disclosure is different from the apparatus 1 in accordance with the above-described embodiment of the disclosure, in that a mold IM has a roller shape.

In accordance with an embodiment, the mold IM may be provided in a roller shape, to be rolled on the manufacturing substrate 200. For example, the mold IM may have a structure in which a plurality of groove patterns are formed on an outer surface of a roller. Accordingly, when the mold IM is rolled on the manufacturing substrate SUB, a light emitting element LD may be aligned by the mold IM.

For example, the apparatus 1 may further include a roller moving part MP and a rolling part RP. The roller moving part MP may move the mold IM in a process direction (e.g., a direction parallel to the first direction DR1). The rolling part RP may rotate the mold IM provided in the roller shape. That is, the mold IM may be rolled on the manufacturing substrate 200, corresponding to a movement operation of the rolling part RP and the roller moving part MP, and light emitting elements LD may be aligned on the manufacturing substrate 200 to correspond to the groove patterns of the mold IM in a process in which the mold IM is rolled.

In accordance with an embodiment, a cleaner CLE may be disposed adjacent to the mold IM provided in the roller shape, and clean the mold IM, similarly to as described above. For example, after an aligning process of the mold IM is performed, the cleaner CLE may clean the mold IM.

However, in some embodiments, while the aligning process of the mode IM is performed, the cleaner CLE may clean the mold IM at the same time. For example, when an area of an outer surface of the mold IM according to a circumference of the mold IM is smaller than an area of the manufacturing substrate 200, it may be adequate that a cleaning process of the cleaner CLE is performed while the aligning process of the mold IM is performed. That is, a surface of the mold IM may perform an aligning process of the light emitting element LD, and a surface of the cleaner CLE may perform a cleaning process. Thus, deterioration of process precision can be prevented or substantially prevented.

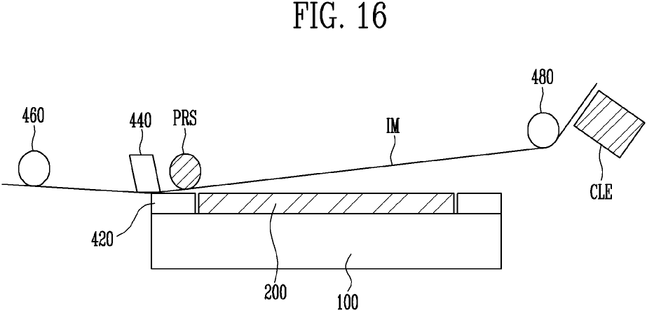

Next, an apparatus 1 for manufacturing a display device in accordance with another embodiment of the disclosure will be described with reference to FIG. 16. FIG. 16 is a view illustrating an apparatus for manufacturing a display device in accordance with another embodiment of the disclosure. FIG. 16 will mainly describe a cross-sectional structure of the apparatus 1 in accordance with another embodiment of the disclosure.

In FIG. 16, descriptions of portions overlapping with those described above may be simplified or may not be repeated, and portions different from those of the above-described embodiment will be mainly described.

Referring to FIG. 16, the apparatus 1 in accordance with another embodiment of the disclosure is different from the apparatus 1 in accordance with the above-described embodiment of the disclosure, in that a press PRS has a roller shape, and a process of aligning a light emitting element LD is performed in a manner that the press PRS having the roller shape pressurizes a mold IM.

In accordance with an embodiment, in the apparatus 1, the press PRS may have a roller shape, and push the mold IM as the press PRS is rolled. In some embodiments, the mold IM may generally have a film shape, and, accordingly, at least a portion of the mold IM may be moved by a roller.

In accordance with an embodiment, the apparatus 1 may include a step difference compensation part 420, a fixing part 440, an in-feed roller 460, and an out-feed roller 480.

The step difference compensation part 420 may be disposed on a stage 100, to compensate for a step difference occurring in a process in which the press PRS is rolled. For example, the step difference compensation part 420 may protrude in a thickness direction of a manufacturing substrate 200 (e.g., the third direction DR3), and generally have a thickness corresponding to a thickness of the manufacturing substrate 200. In some embodiments, the step difference compensation part 420 may be disposed at a side corresponding to a position before the press PRS is rolled, as a first side of the manufacturing substrate 200. The step difference compensation part 420 may be disposed at a side corresponding to a position after the press PRS is rolled, as a second side of the manufacturing substrate 200.

The fixing part 440 may pressurize a portion of an area extending from the mold IM, thereby thoroughly fixing a position of the mold IM. In some embodiments, the fixing part 440 may be disposed adjacent to the position before the press PRS is rolled.

The in-feed roller 460 and the out-feed roller 480 may be rotated, to move the mold IM. For example, a portion of the mold IM may be moved in a direction by the in-feed roller 460, to be provided adjacent to the manufacturing substrate 200, and a portion of the mold IM may be moved in a direction by the out-feed roller 480, to be spaced apart from the manufacturing substrate 200.

In accordance with an embodiment, the press PRS may pressurize the mold IM as the press PRS is rolled on the mold IM. That is, the press PRS may sequentially push another area from a partial area of the mold IM, and, accordingly, an alignment operation of light emitting elements LD can be performed on the entire manufacturing substrate 200.

However, the structure of the apparatus 1 in accordance with an embodiment of the disclosure is not limited to the above-described example. For example, in some embodiments, the apparatus 1 may further include a tension roller, to maintain tension of the mold IM according to a reference.

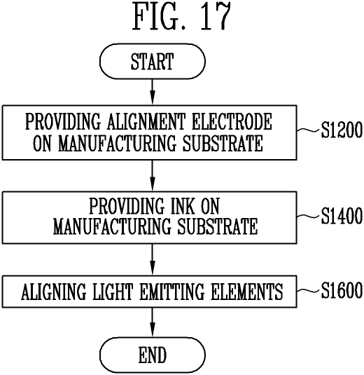

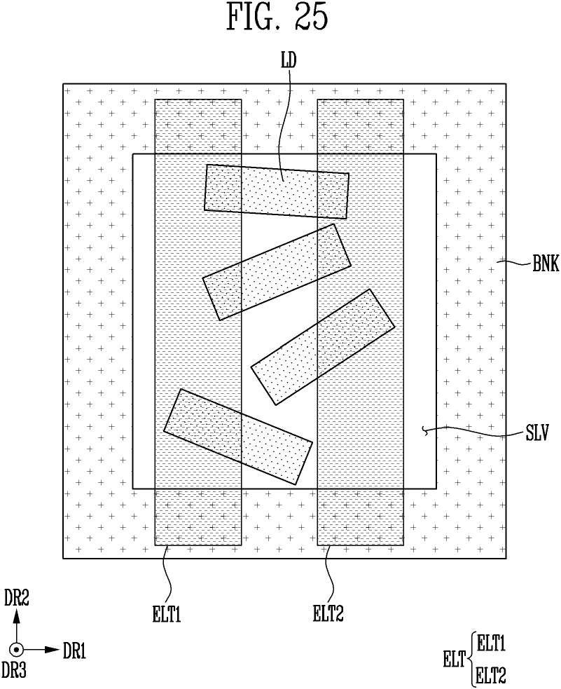

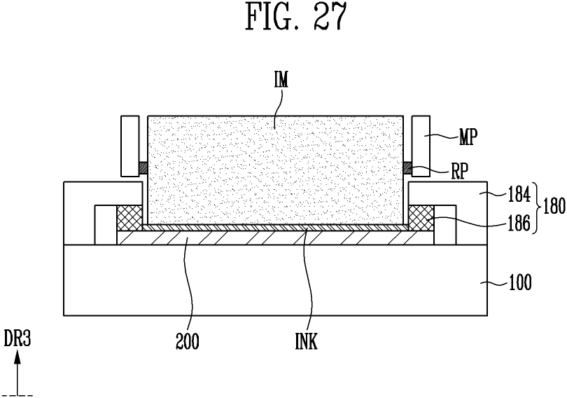

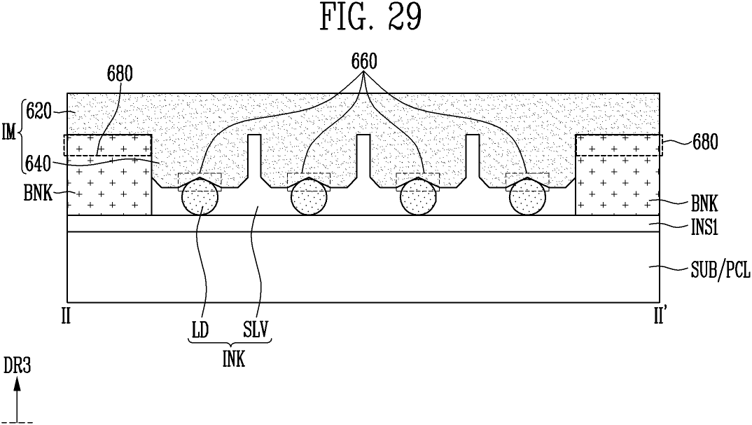

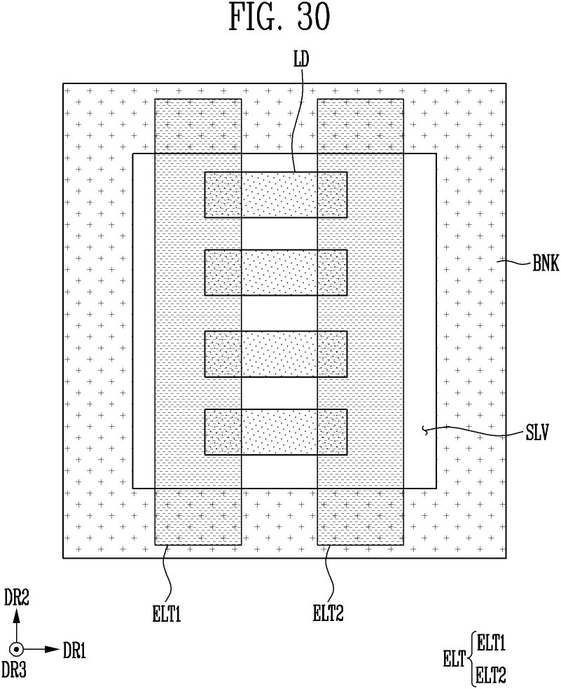

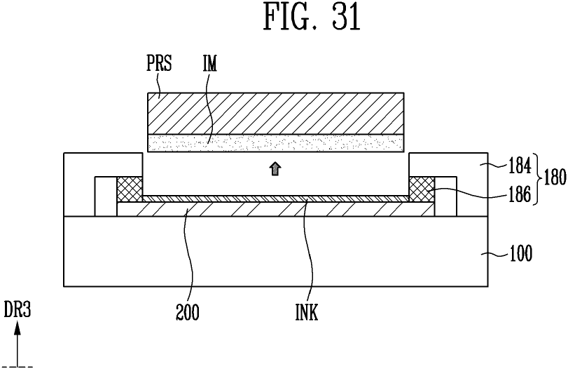

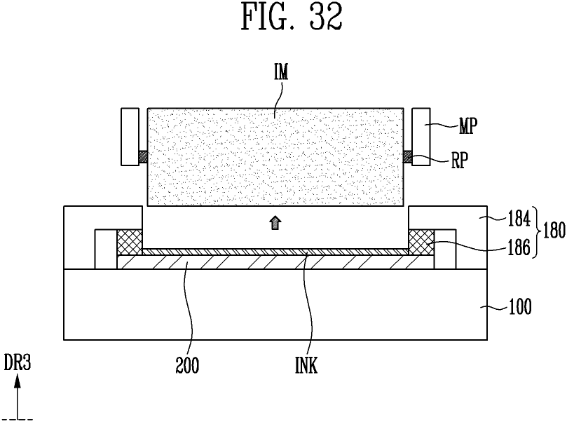

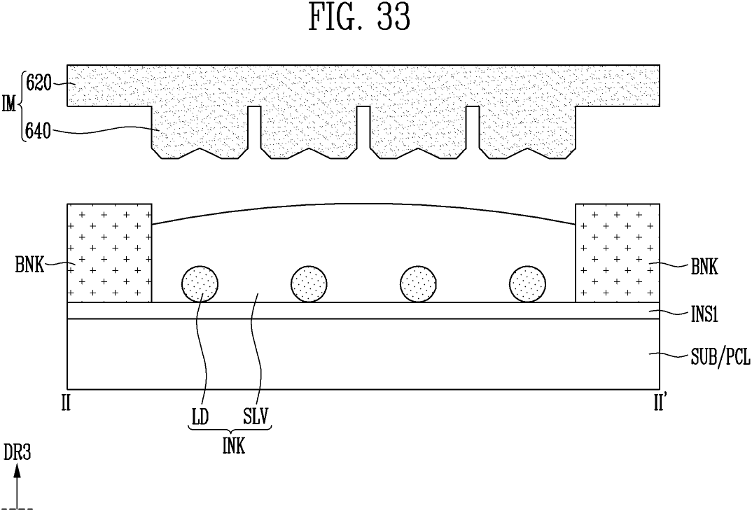

Next, a manufacturing method of the display device DD in accordance with an embodiment of the disclosure will be described with reference to FIGS. 17 to 36. In FIGS. 17 to 36, descriptions of portions overlapping with those described above may be simplified or may not be repeated.

First, a manufacturing method of the display device DD in accordance with an embodiment of the disclosure will be described with reference to FIGS. 17 to 34. For convenience of description, first to third embodiments respectively corresponding to individual steps in the manufacturing method will be described.

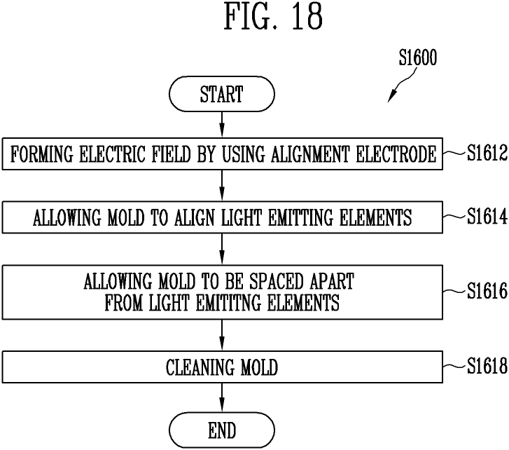

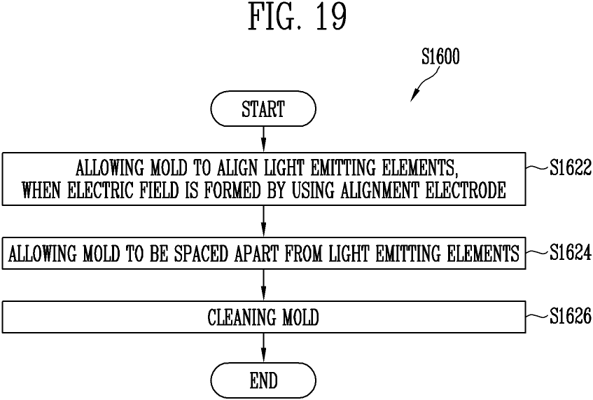

FIGS. 17 to 19 are flowcharts illustrating a manufacturing method of a display device in accordance with an embodiment of the disclosure. FIG. 17 may be a flowchart schematically illustrating a manufacturing method of the display device DD in accordance with an embodiment of the disclosure. FIGS. 18 and 19 may be flowcharts illustrating in further detail a step S1600 of aligning light emitting elements in accordance with an embodiment of the disclosure. For example, each of FIGS. 18 and 19 may illustrate step the S1600 of aligning the light emitting elements in accordance with an individual embodiment of the disclosure.

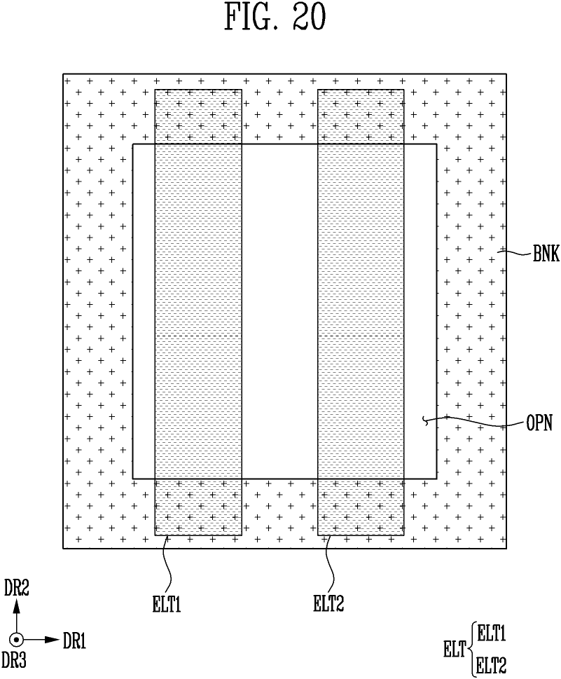

FIGS. 20, 25, and 30 are process (or operation) plan views illustrating a manufacturing method of a display device in accordance with an embodiment of the disclosure. FIGS. 20, 25, and 30 may schematically illustrate a structure corresponding to the sub-pixel SPXL described above with reference to FIG. 4.

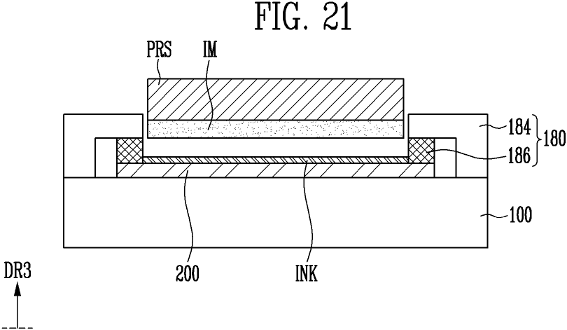

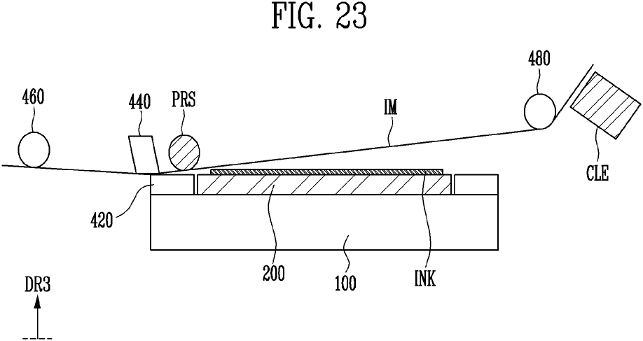

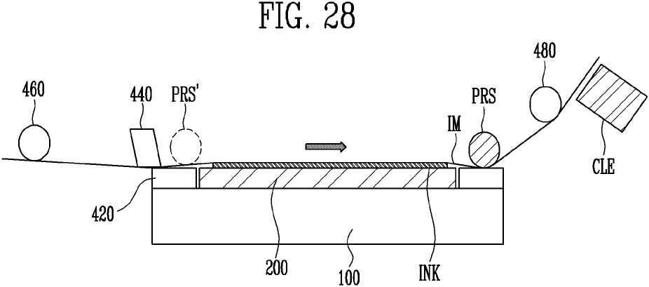

FIGS. 21 to 23, 26 to 28, 31, 32, and 34 are process (or operation) plan views illustrating an apparatus for manufacturing a display device in accordance with an embodiment of the disclosure. FIGS. 21, 26, 31, and 34 may be cross-sectional views schematically illustrating the apparatus 1 in accordance with a first embodiment of the disclosure (e.g., an embodiment described above with respect to FIGS. 6 to 9). FIGS. 22, 27, and 32 may be cross-sectional views schematically illustrating the apparatus 1 in accordance with a second embodiment of the disclosure (e.g., an embodiment described above with respect to FIGS. 14 and 15). FIGS. 23 and 28 may be cross-sectional views schematically illustrating the apparatus 1 in accordance with a third embodiment of the disclosure (e.g., an embodiment described above with respect to FIG. 16).

FIGS. 24, 29, and 33 are process (or operation) plan views illustrating a manufacturing method of a display device in accordance with an embodiment of the disclosure. FIGS. 24, 29, and 33 may illustrate a schematic cross-sectional area taken along the line II-II′ shown in FIG. 4.

Referring to FIG. 17, the manufacturing method of the display device DD in accordance with an embodiment of the disclosure may include a step S1200 of providing an alignment electrode on a manufacturing substrate, a step S1400 of providing an ink on the manufacturing substrate, and the step S1600 of aligning light emitting elements.

Referring to FIGS. 17 and 20, in the step S1200 of providing the alignment electrode on the manufacturing substrate, the alignment electrode ELT may be patterned (or formed) on the manufacturing substrate 200.

Although not shown in the drawings, before the alignment electrode ELT is disposed, a pixel circuit layer PCL may be formed on the manufacturing substrate 200. Individual components of the pixel circuit layer PCL may be formed by patterning a conductive layer (or metal layer), an inorganic material, an organic material, or the like through an ordinary process using a mask.

In the step S1200 of providing the alignment electrode on the manufacturing substrate, a first electrode ELT1 and a second electrode ELT2 may be formed, such that a path through which light emitting elements LD are arranged can be defined.

After the alignment electrode ELT is formed, a first insulating layer INS1 may be disposed on the alignment electrode ELT, a bank BNK protruding in a thickness direction of the manufacturing substrate 200 may be disposed (or provided). Accordingly, an opening OPN surrounded by the bank BNK may be formed.

Referring to FIGS. 17 and 21 to 25, in the step S1400 of providing the ink on the manufacturing substrate, the ink INK may be supplied (e.g., sprayed) onto the manufacturing substrate 200. The ink INK may be provided by the ink printer 160 described above with reference to FIG. 6, which can spray a fluid.

In accordance with an embodiment, the ink INK may be a liquid mixture which can be discharged by the ink printer 160. For example, the ink INK may include light emitting elements LD and a solvent SLV. In some embodiments, the light emitting element LD may be contained by a solid of a certain range (e.g., a predetermined range) in the ink INK. In some embodiments, the solvent SLV may have fluidity, and the light emitting elements LD can be dispersed in the solvent SLV. The solvent SLV may be a liquid-phase material, instead of a solid-phase material, in which the light emitting elements LD are dispersed and provided. In some embodiments, the solvent SLV may include an organic solvent. For example, the solvent SLV may be any of propylene glycol methyl ether acetate (PGMEA), dipropylene glycol n-propyl ether (DGPE), and triethylene glycol n-butyl ether (TGBE). However, the disclosure is not limited to the above-described examples, and the solvent SLV may include various organic solvents.

In the step S1400 of providing the ink on the manufacturing substrate, the ink INK may be accommodated in a space defined by the bank BNK. In some embodiments, the light emitting element LD included in the ink INK may be randomly located on the first insulating layer INS1. Since FIG. 24 is a view illustrating a structure corresponding to FIG. 4, the light emitting element LD may be in a state in which the light emitting element LD is normally arranged, when a bottom surface of the light emitting element LD is disposed to be illustrated in a cross-section in FIG. 24.

In the step S1400 of providing the ink on the manufacturing substrate, a press PRS and a mold IM according to each of the first to third embodiments of the disclosure (see FIGS. 21 to 23 may be provided to be spaced apart from the ink INK.

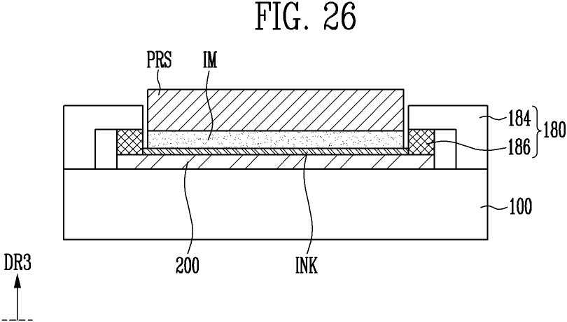

Referring to FIGS. 26 to 30, in the step S1600 of aligning the light emitting elements, the light emitting elements LD may be aligned according to a certain arrangement (e.g., a predetermined arrangement). For example, the light emitting elements LD may be aligned to correspond to a pattern structure of the mold IM.

In accordance with the disclosure, the step S1600 of aligning the light emitting elements may be performed in various manners.

First, step S1600 of aligning the light emitting elements will be described in conjunction with FIG. 18.

In an embodiment, referring to FIG. 18, the step S1600 of aligning the light emitting elements may include a step S1612 of forming an electric field by using the alignment electrode, a step S1614 of allowing the mold to align the light emitting elements, a step S1616 of allowing the mold to be spaced apart from the light emitting elements, and a step S1618 of cleaning the mold.

In accordance with an embodiment, the light emitting elements LD may be aligned by performing the step S1614 of allowing the mold to align the light emitting elements after the step S1612 of forming the electric field by using the alignment electrode is performed. However, the disclosure is not necessarily limited to the above-described example. In some embodiments, the step S1612 of forming the electric field by using the alignment electrode may be performed after the step S1614 of allowing the mold to align the light emitting elements is performed.

Referring to FIGS. 18 and 26 to 30, in the step S1612 of forming the electric field by using the alignment electrode, an electrical signal may be provided to the first electrode ELT1 and the second electrode ELT2, and, accordingly, an electric field can be formed between the first electrode ELT1 and the second electrode ELT2. In some embodiments, the light emitting element LD may be moved by a force (e.g., a dielectrophoresis (DEP) force) based on the formed electric field. In some embodiments, the electrical signal may be an AC signal. For example, the AC signal may be any of a sine wave, a triangular wave, a square wave, a trapezoidal wave, and a pulse wave. However, the disclosure is not limited thereto, and the AC signal may have various AC signal forms known in the art.

Next, referring to FIGS. 18 and 26 to 30, in the step S1614 of allowing the mold to align the light emitting elements, the light emitting elements LD may be aligned corresponding to the pattern structure of the mold IM. For example, in this step, each of the light emitting elements LD may be rotated to correspond to a light emitting element area 660 of a protrusion part 640. That is, while the protrusion part 640 is in contact with the light emitting element LD in the light emitting element area 660, the protrusion part 640 may apply a pressure such that a pose of the light emitting element LD is changed.

In accordance with an embodiment, light emitting element areas 660 may respectively correspond to the light emitting elements LD, and, therefore, each of the light emitting elements LD may be rotated corresponding to a corresponding light emitting element area 660. Accordingly, as described above, an alignment degree of the light emitting elements LD can be improved.

That is, when the light emitting element LD is aligned by simply using an electric field, some light emitting elements LD may be abnormally aligned. However, since the mold IM aligns the light emitting element LD to correspond to a desired arrangement structure of a user, the light emitting element LD can be normally arranged. Moreover, since the light emitting element area 660 corresponds to each of individual light emitting elements LD, an agglomeration phenomenon of the light emitting elements LD can be prevented or substantially prevented.

In this step, the mold IM of the apparatus 1 in accordance with the first embodiment of the disclosure may be pressurized by the press PRS (see FIG. 26). Accordingly, as described above, while the mold IM is in contact with the light emitting element LD, the mold IM may apply a pressure such that the light emitting element LD is rotated. In accordance with the first embodiment of the disclosure, a surface of the mold IM, on which a plurality of groove patterns is formed (e.g., an area in which the light emitting element areas 660 are formed), may be in contact (e.g., entirely in contact) with the light emitting elements LD. That is, since the mold IM in accordance with the first embodiment of the disclosure has a shape generally extending on a plane, the light emitting elements LD on the manufacturing substrate 200 can be entirely (or concurrently, or simultaneously) aligned.

Also, in this step, the mold IM of the apparatus 1 in accordance with the second embodiment of the disclosure may be rolled to be in contact with the light emitting element LD, and apply a pressure such that the light emitting element LD is rotated. That is, the mold IM having a roller shape may be rotated by the rolling part RP, be moved along the process direction by the roller moving part MP, and rotate the light emitting element LD while the mold IM is rolled and moved.

Also, in this step, the press PRS of the apparatus 1 in accordance with the third embodiment of the disclosure may be rolled along the process direction, and pressurize the mold IM while the press PRS is rolled. Accordingly, the mold IM can sequentially apply a pressure to the light emitting elements LD. In some embodiments, a position of the press PRS before the press PRS is rolled is indicated by a dotted line PRS′, and a position of the press PRS after the press PRS is rolled is indicated by a solid line.

Meanwhile, in this step, movement of the mold IM is restricted by the bank BNK, such that abnormal movement of the mold IM can be prevented or substantially prevented. For example, the protrusion part 640 may not be disposed in a partial area of a base part 620, and, accordingly, a mold movement restriction area 680 may be formed. In some embodiments, the mold IM receives a pressure by the press PRS, but the base part 620 is in contact with the bank BNK in the mold movement restriction area 680, such that excessive movement of the mold IM can be restricted. In some embodiments, when the mold IM and the bank BNK are in contact with each other in the mold movement restriction area 680, a portion of the mold IM may be in contact with the light emitting element LD.

Accordingly, an excessive pressure applied to the light emitting element LD can be prevented or substantially prevented even while the mold IM rotates the light emitting element LD by applying a pressure to the light emitting element LD. Thus, damage of the light emitting element LD can be prevented or substantially prevented.

Referring to FIGS. 18 and 31 to 33, in the step S1616 of allowing the mold to be spaced apart from the light emitting elements, the mold IM may be spaced apart from the light emitting element LD on the manufacturing substrate 200.

For example, the press PRS and the mold IM may be moved in the third direction DR3, to be spaced apart from the ink INK. The light emitting elements LD may be in a state in which the light emitting elements LD are aligned by the mold IM to correspond to a desired structure of a user.

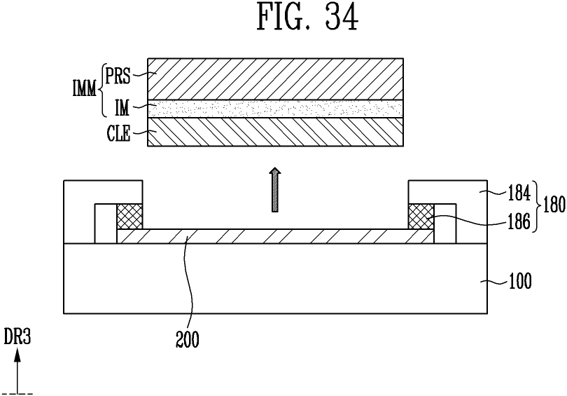

Referring to FIGS. 18 and 34, in the step S1618 of cleaning the mold, a cleaner CLE may clean the mold IM.

For example, the light emitting element LD and the solvent SLV, which remain on the mold IM, may be removed. Accordingly, the mold IM may be provided in a state suitable for performing a cleaning process. In an example, a structure in which the cleaner CLE in accordance with the first embodiment of the disclosure cleans the mold IM is illustrated in FIG. 34. In addition, the cleaner CLE is disposed on the bottom thereof with respect to the gravity direction, such that the ink INK having a fluidal property can be more efficiently removed.

When the apparatus 1 in accordance with the second embodiment of the disclosure is used, the cleaner CLE disposed at a side of the mold IM having a roller shape may clean the mold IM. When the apparatus 1 in accordance with the third embodiment of the disclosure is used, the cleaner CLE disposed at a side of the out-feed roller 480 may clean the mold IM.

Next, step S1600 of aligning the light emitting elements in accordance with another embodiment of the disclosure will be described in conjunction with FIG. 19.

Referring to FIG. 19, the step S1600 of aligning the light emitting elements may include a step S1622 of allowing the mold to align the light emitting elements when an electric field is formed by using the alignment electrode, a step S1624 of allowing the mold to be spaced apart from the light emitting elements, and a step S1626 of cleaning the mold.

That is, in the step S1600 of aligning the light emitting elements in accordance with this embodiment is different from the step S1600 of aligning the light emitting elements in accordance with the embodiment described above with reference to FIG. 18, in that an operation in which the alignment electrode ELT forms an electric field and an operation in which the mold IM aligns the light emitting element LD are concurrently (e.g., simultaneously) performed.

For example, the light emitting element LD may be rotated by the mold IM while being rotated based on the electric field formed by the alignment electrode ELT. An alignment operation of the light emitting element LD is performed by two kinds of external forces. Thus, the alignment operation of the light emitting element LD can be more thoroughly performed.

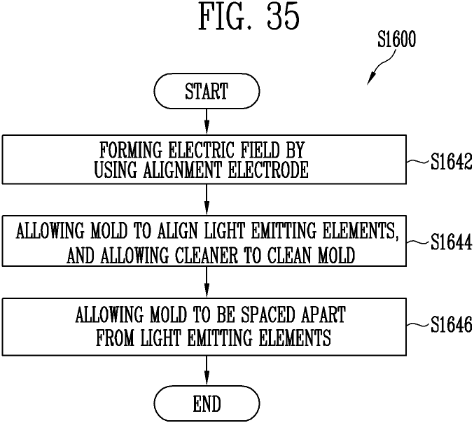

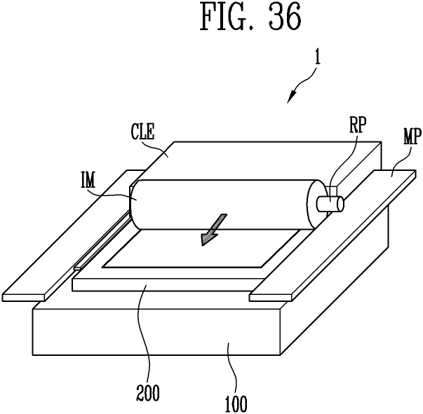

Next, a manufacturing method of the display device DD in accordance with another embodiment of the disclosure will be described with reference to FIGS. 35 and 36. In FIGS. 35 and 36, descriptions of portions overlapping with those described above may be simplified or may not be repeated.

FIG. 35 is a flowchart illustrating a manufacturing method of a display device in accordance with another embodiment of the disclosure. FIG. 36 is a schematic perspective view illustrating a manufacturing method of a display device in accordance with another embodiment of the disclosure.

The manufacturing method of the display device DD in accordance with another embodiment of the disclosure uses the apparatus 1 in accordance with the second embodiment of the disclosure, and may be suitable when an area of an outer surface of the mold IM according to a circumference of the mold IM is smaller than an area of the manufacturing substrate 200.

In accordance with an embodiment, the manufacturing method of the display device DD in accordance with another embodiment of the disclosure may include a step S1642 of forming an electric field by using an alignment electrode, a step S1644 of allowing a mold to align light emitting elements and allowing a cleaner to clean the mold, and a step S1646 of allowing the mold to be spaced apart from the light emitting elements.

In accordance with an embodiment, an operation in which the mold IM aligns the light emitting element LD while rotating the light emitting element LD and an operation in which the cleaner CLE cleans the mold IM may be performed through a same process. For example, the mold IM having a roller shape may be rolled in the process direction (e.g., the first direction DR1), and apply a pressure to the light emitting element LD. While a surface or side of the mold IM is in contact with the ink INK including the light emitting element LD, another surface or side of the mold IM may be cleaned by the cleaner CLE. Accordingly, while the mold IM aligns the light emitting element LD, a surface of the mold IM may be continuously cleaned, such that an additional process is not separately accompanied even when the area of the outer surface of the mold IM according to the circumference of the mold IM is smaller than the area of the manufacturing substrate 200. Thus, a manufacturing process can be simplified.

In accordance with the disclosure, a manufacturing method of a display device and an apparatus for manufacturing a display device, which can improve an alignment degree of a light emitting element, are provided.

Some example embodiments have been disclosed herein, and although specific terms are employed, they are used and are to be interpreted in a generic and descriptive sense and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it is to be understood by those of skill in the art that various changes in form and details may be made without departing from the spirit and scope of the disclosure as set forth in the following claims.

What is claimed is:

1. A method of manufacturing a display device, the method comprising:
providing an ink comprising light emitting elements on a manufacturing substrate; and
aligning the light emitting elements by using a mold comprising a plurality of groove patterns.

2. The method of claim 1, wherein the aligning of the light emitting elements comprises:
allowing a press arranged on a surface of the mold to push the mold;
allowing the mold to apply a pressure to the light emitting elements; and
allowing the light emitting elements to be aligned corresponding to the plurality of groove patterns of the mold.

3. The method of claim 2, wherein the mold comprises light emitting element areas, and
wherein the allowing of the mold to apply the pressure to the light emitting elements is performed such that positions at which the light emitting elements are aligned respectively correspond to positions of the light emitting element areas.

4. The method of claim 3, wherein the light emitting element areas are groove areas formed in the mold.

5. The method of claim 1, wherein the aligning of the light emitting elements comprises allowing the plurality of groove patterns of the mold to contact the light emitting elements located on the manufacturing substrate.

6. The method of claim 1, wherein the mold has a roller shape, and
wherein the aligning of the light emitting elements comprises allowing the mold to be rolled on the manufacturing substrate.

7. The method of claim 1, wherein the aligning of the light emitting elements comprises allowing the mold to apply a pressure to the light emitting elements when a press having a roller shape is rolled on the mold.

8. The method of claim 1, further comprising providing a bank protruding in a thickness direction of the manufacturing substrate on the manufacturing substrate,
wherein the providing of the ink comprises allowing the ink to be accommodated in a space defined by the bank,
wherein the mold comprises:
a base part; and
a protrusion part connected to the base part,
wherein the mold further comprises a mold movement restriction area in which the protrusion part is not located, and
wherein the aligning of the light emitting elements comprises:
allowing a portion of the mold to apply a pressure to the light emitting elements; and
allowing the mold to contact the bank in the mold movement restriction area.

9. The method of claim 1, further comprising allowing a cleaner to clean a surface of the mold, after the aligning of the light emitting elements.

10. The method of claim 1, further comprising allowing a cleaner to clean a surface of the mold,
wherein the mold has a roller shape,
wherein an area of an outer surface of the mold according to a circumference of the mold is smaller than an area of the manufacturing substrate, and
wherein the cleaning of the surface of the mold is concurrently performed with the aligning of the light emitting elements.

11. The method of claim 1, further comprising:
providing an alignment electrode on the manufacturing substrate; and
forming an electric field by using the alignment electrode,
wherein the light emitting elements are aligned based on the electric field.

12. The method of claim 11, wherein the forming of the electric field and the aligning of the light emitting elements by using the mold are concurrently performed.

13. The method of claim 1, wherein the mold comprises:
a base part; and
a protrusion part connected to the base part,
wherein the protrusion part comprises a light emitting element area formed such that a portion of the protrusion part is recessed, and
wherein a direction in which the light emitting elements aligned on the manufacturing substrate extend is the same as a direction in which the light emitting element area extends.

14. The method of claim 1, wherein the mold has an elastic property.

15. A display device manufactured according to the method of claim 1.

16. An apparatus for manufacturing a display device, the apparatus comprising:
a mold located on a stage; and
a press configured to apply, to the mold, a pressure facing the stage from the mold,
wherein the mold comprises:
a base part; and
a protrusion part connected to the base part, the protrusion part comprising a groove area formed such that a portion of the protrusion part is recessed.

17. The apparatus of claim 16, wherein the press and the mold are moved to be adjacent to or spaced apart from the stage.

18. The apparatus of claim 16, wherein the mold has a roller shape.

19. The apparatus of claim 16, wherein the press has a roller shape.

20. The apparatus of claim 16, further comprising a probe arranged on the stage, the probe configured to provide an electrical signal such that an electric field is formed on a manufacturing substrate provided on the stage.
